(19) United States
(12) Patent Application Publication
(10) Pub. No.: US 2013/0026474 A1
(43) Pub. Date: Jan. 31, 2013

(54) STORAGE CAPACITOR ARCHITECTURE FOR PIXEL STRUCTURE AND MANUFACTURING METHOD THEREOF

(71) Applicant: Chihtsung Kang, Shenzhen (CN)

(72) Inventor: Chihtsung Kang, Shenzhen (CN)

(73) Assignee: SHENZHEN CHINA STAR OPTOELECTRONICS TECHNOLOGY CO. ltd, Shenzhen (CN)

(21) Appl. No.: 13/264,875

(22) PCT Filed: Sep. 5, 2011
(86) PCT No.: PCT/CN11/79324

§ 371 Date: Oct. 17, 2011

(30) Foreign Application Priority Data
Jul. 26, 2011 (CN) 201110210350.7

(51) Int. Cl. H01L 33/38; H01G 4/005

(52) U.S. Cl. 257/59; 361/303; 257/71; 438/38; 257/E33.065

(57) ABSTRACT

A storage capacitor architecture for pixel structure and manufacturing method thereof are described. The storage capacitor architecture includes a substrate, a first electrode, an insulating layer and a second electrode. The first electrode has a first concave and convex structure. The insulating layer is disposed on the first concave and convex structure of the first electrode. The second electrode is disposed on the insulating layer and has a second concave and convex structure. The first concave and convex structure and the second concave and convex structure form an interdigitated space and the insulating layer is disposed in the interdigitated space to solve the problem of decreased aperture ratio of the LCD panel.

### FIELD OF THE INVENTION

The present invention relates to a semiconductor architecture and manufacturing method thereof, and more particularly to a storage capacitor architecture, a manufacturing method thereof and a pixel structure employing the storage capacitor architecture.

### BACKGROUND OF THE INVENTION

A thin-film transistor (TFT) array is a key component of the liquid crystal display (LCD). The TFT array is composed of a plurality of pixel units, a plurality of scan lines and a plurality of data lines.

The pixel units are electrically connected to the scan lines and the data lines. Each of the pixel units has a thin-film transistor, a liquid-crystal capacitor (CLC) and a storage capacitor (CS). In other words, the CLC of the pixel unit is charged to drive the liquid crystal molecules within the liquid crystal layer for displaying the image on the LCD panel. Meanwhile, the CSs connected to the data lines are charged wherein the charged CSs are used to maintain the voltage potential of the CLC to be a predetermined value for keeping the voltage potential to be constant in the both terminals of the CLC by the charged CSs before the data of the data lines are updated.

FIG. 1 is a schematic cross-sectional view of a conventional metal-insulator-metal structure of storage capacitor 100. The storage capacitor 100 of TFT uses an insulating layer 106 disposed between a lower metal layer 102 and an upper metal layer 104 to form the storage capacitor (CS). A passivation layer 108 is deposited on the upper metal layer 104 and a transparent electrode layer 110 is electrically connected to the upper metal layer 104. The storage capacitor 100 is used to maintain the voltage potential of pixel structure wherein the lower metal layer 102 and an upper metal layer 104 may be replaced by indium tin oxide (ITO). However, the material of the lower metal layer 102 and an upper metal layer 104 is metal-to-ITO or metal-to-metal. When the area (proportional to the length “L”) between the lower metal layer 102 and an upper metal layer 104 is increased, the aperture ratio of the aperture ratio of the pixel structure is disadvantageous, which result in decreased transmittance and downgraded image quality of the LCD panel. Consequently, there is a need to develop a novel storage capacitor and pixel structure thereof to solve the aforementioned problem of the decreased aperture ratio.

### SUMMARY OF THE INVENTION

One objective of the present invention is to provide a storage capacitor architecture, a manufacturing method thereof and a pixel structure employing the storage capacitor architecture to solve the problem of decreased aperture ratio of the LCD panel.

According to the above objective, the present invention is to provide a storage capacitor architecture. The storage capacitor architecture includes a substrate, a first electrode, an insulating layer and a second electrode. The first electrode is disposed on the substrate and has a first concave and convex structure. The insulating layer is disposed on the first concave and convex structure of the first electrode. The second electrode is disposed on the insulating layer and has a second concave and convex structure wherein the first concave and convex structure and the second concave and convex structure form an interdigitated space and the insulating layer is disposed in the interdigitated space to form the storage capacitor architecture.

In one embodiment, the first electrode comprises a common line.

In one embodiment, the first electrode comprises a scan line.

In one embodiment, the first concave and convex structure and the second concave and convex structure are selected from one consisting of a three-dimensional straight line shape, a three-dimensional inclined line shape, a three-dimensional concentric circle shape and a three-dimensional intersectional line shape.

According to the above objective, the present invention is to provide a pixel structure employing the storage capacitor architecture. The pixel structure with the storage capacitor architecture includes a thin-film transistor (TFT), a first electrode, an insulating layer, a second electrode, a passivation layer and a transparent electrode. The first electrode has a first concave and convex structure. The insulating layer is disposed on the first concave and convex structure of the first electrode. The second electrode is disposed on the insulating layer and has a second concave and convex structure wherein the first concave and convex structure and the second concave and convex structure form an interdigitated space and the insulating layer is disposed in the interdigitated space to foam the storage capacitor architecture. The passivation layer is formed on the second electrode and the insulating layer wherein a portion of the second electrode is exposed. The transparent electrode is formed on the passivation layer for electrically connecting the exposed second electrode with the TFT. In one embodiment, the first electrode comprises a common line.

In one embodiment, the first electrode comprises a scan line.

In one embodiment, the first concave and convex structure and the second concave and convex structure are selected from one consisting of a three-dimensional straight line shape, a three-dimensional inclined line shape, a three-dimensional concentric circle shape and a three-dimensional intersectional line shape.

According to the above objective, the present invention is to provide a manufacturing method of a storage capacitor architecture. The manufacturing method includes the following steps:

(a) forming a first conductive layer on a substrate;

(b) patterning the first conductive layer for forming a first electrode having a first concave and convex structure;

(c) forming an insulating layer on the substrate and the first electrode;

(d) farming a second conductive layer on the insulating layer;

(e) pattering the second conductive layer for forming a second electrode having a second concave and convex structure, wherein the first concave and convex structure and the second concave and convex structure form an interdigitated space and the insulating layer is disposed in the interdigitated space;

(f) forming a passivation layer on the second electrode and the insulating layer and exposing a portion of the second electrode; and

(g) forming a transparent electrode layer on the passivation layer and the exposed second electrode for electrically connecting the transparent electrode layer to the exposed second electrode.

In one embodiment, the material of the first electrode is metal.

In one embodiment, the material of the second electrode is either metal or indium tin oxide (ITO).

In one embodiment, the first concave and convex structure of the first electrode is formed by either a gray tone mask or a half tone mask during the step (b).

In one embodiment, the first electrode comprises a common line.

In one embodiment, the first electrode comprises a scan line.

In one embodiment, the first concave and convex structure and the second concave and convex structure are selected from one consisting of a three-dimensional straight line shape, a three-dimensional inclined line shape, a three-dimensional concentric circle shape and a three-dimensional intersectional line shape.

The present invention utilizes the first concave and convex structure of the first electrode and the second concave and convex structure of the second electrode to increase the average length for enlarging the opposite area of the first electrode and the second electrode to raise the capacitance of the storage capacitor architecture while the aperture ratio of the pixel structure is constant. Furthermore, in comparison with conventional storage capacitor of the pixel structure, the present invention can adjust the average length to obtain the same capacitance value. The opposite area between the first electrode and the second electrode is decreased to increase the aperture ratio of the pixel structure.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic cross-sectional view of a conventional metal-insulator-metal structure of storage capacitor;

FIG. 2 is a schematic top view of a pixel structure having a storage capacitor architecture according to one embodiment of the present invention;

FIG. 3 is a schematic cross-sectional view of storage capacitor architecture shown in FIG. 2 along line A-A′ according to one embodiment of the present invention;

FIGS. 4A-4D are three-dimensional views of concave and convex structures formed on the storage capacitor architecture according to one embodiment of the present invention; and

FIGS. 5A-5E are flow chart of manufacturing the storage capacitor architecture according to one embodiment of the present invention.

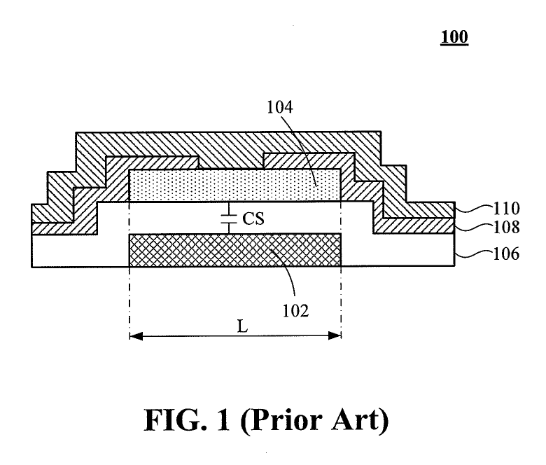

### DETAILED DESCRIPTION OF THE PREFERRED EMBODIMENTS

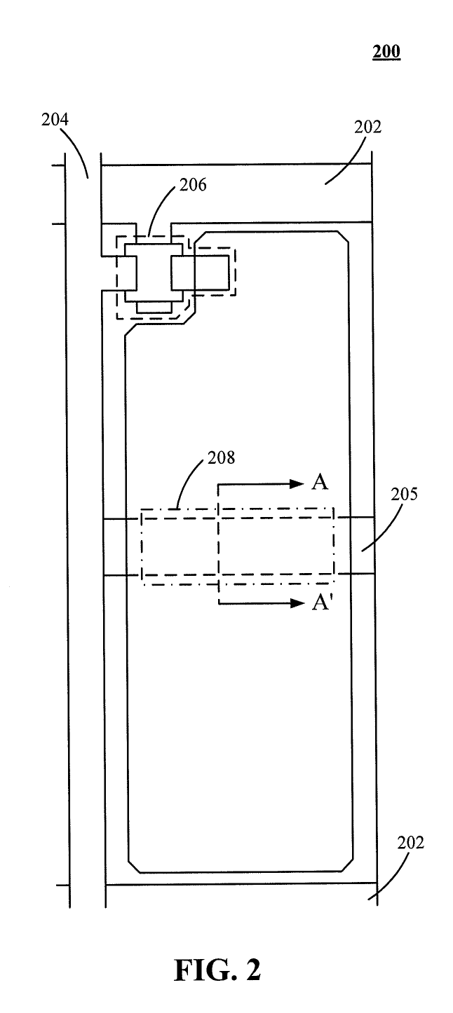

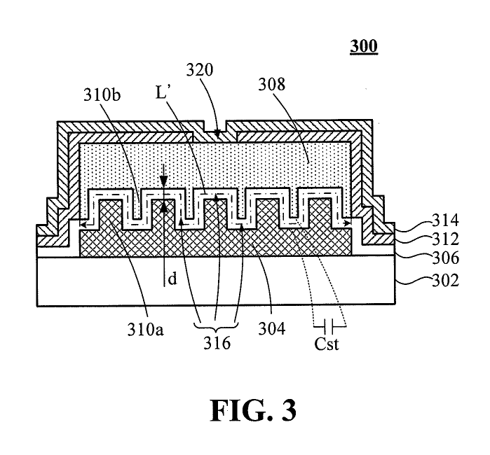

Please refer to FIG. 2 and FIG. 3. FIG. 2 is a schematic top view of a pixel structure 200 having a storage capacitor architecture 300 according to one embodiment of the present invention. FIG. 3 is a schematic cross-sectional view of storage capacitor architecture 300 shown in FIG. 2 along line A-A′ according to one embodiment of the present invention. In FIG. 2, the pixel structure 200 is electrically connected to a scan line 202 and a data line 204 and has a thin-film transistor 206, a liquid-crystal capacitor (CLC) (not shown) and a storage capacitor (CS) 208. Specifically, in the pixel structure, the CLC is charged to drive the liquid crystal molecules within the liquid crystal layer for displaying the image on the LCD panel. Meanwhile, the CSs 208 connected to the data lines 204 are charged wherein the charged CSs 208 are used to maintain the voltage potential of the CLC to be a predetermined value for keeping the voltage potential to be constant in the both terminals of the CLC by the charged CSs 208 before the data of the data lines 204 are updated.

In FIG. 3, the storage capacitor architecture 300 includes a substrate 302, a first electrode 304, an insulating layer 306 and a second electrode 308. The insulating layer 306 is disposed between the first electrode 304 and the second electrode 308 and a passivation layer 312 and a transparent electrode layer 314 are sequentially formed on the second electrode 308. The first electrode 304 is disposed on the substrate 302 and has a first concave and convex structure 310a. The insulating layer 306 is disposed on the first concave and convex structure 310a of the first electrode 304. The second electrode 308 is disposed on the insulating layer 306 and has a second concave and convex structure 310b wherein the first concave and convex structure 310a and the second concave and convex structure 310b form an interdigitated space 316 and the insulating layer 306 is disposed in the interdigitated space 316 to form the storage capacitor architecture 300. That is, the first concave and convex structure 310a of the first electrode 304 is interdigitated to the second concave and convex structure 310b of the second electrode 308 therebetween and the first concave and convex structure 310a and the second concave and convex structure 310b constructs the interdigitated space 316 having a thickness “d”. The interdigitated space 316 is filled with the insulating layer 306 for generating a capacitance value Cst of the storage capacitor architecture 300. Particularly, the capacitance value Cst of the storage capacitor architecture 300 is defined as follows.

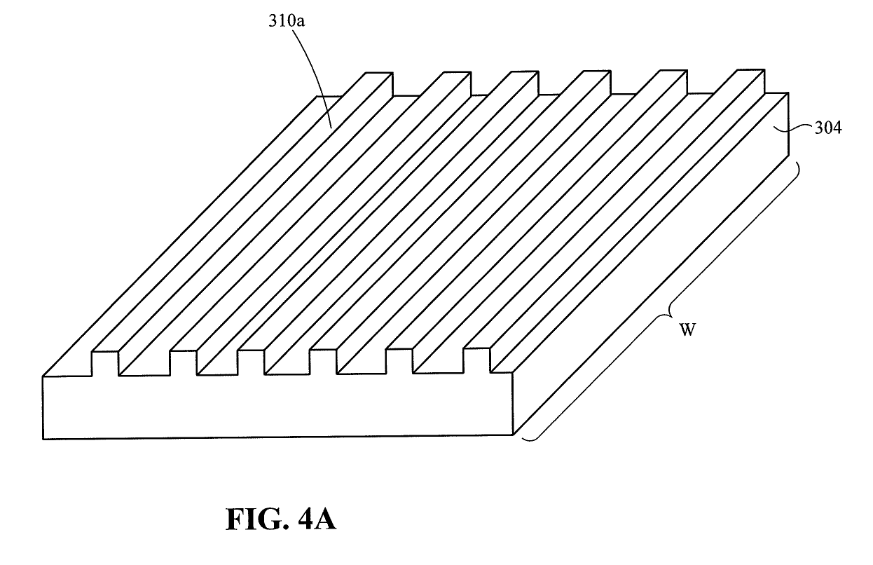

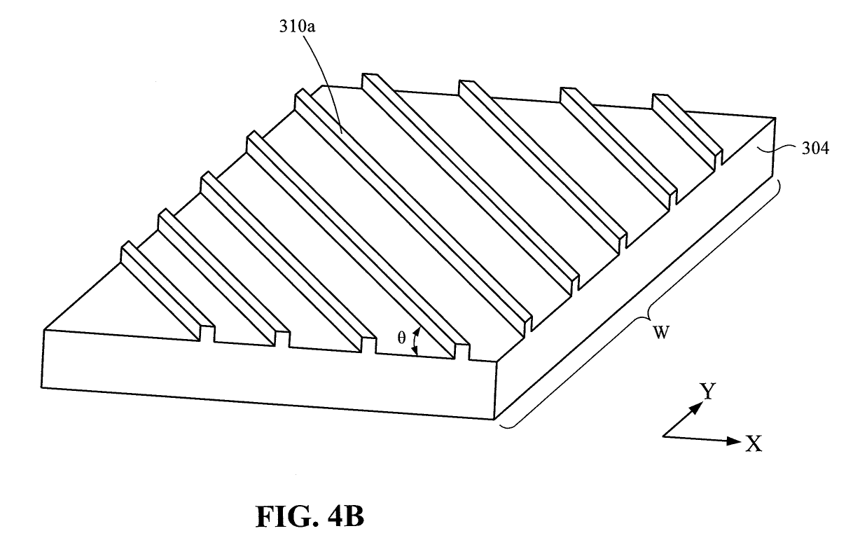

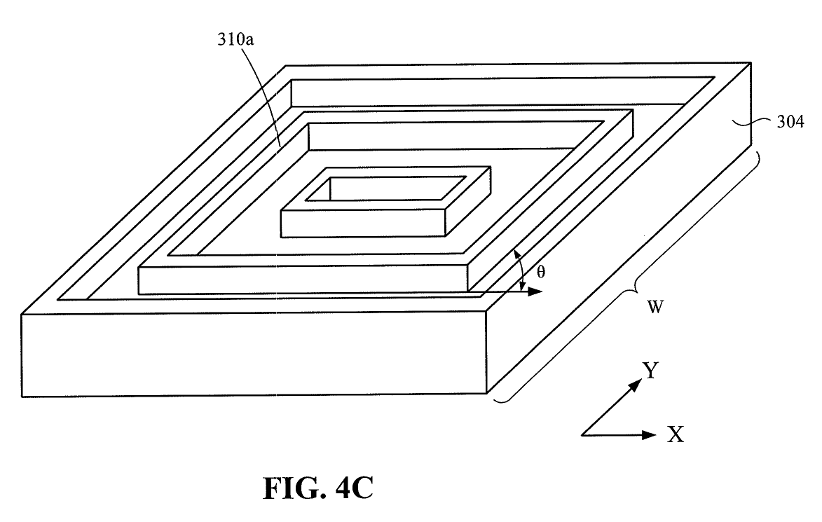

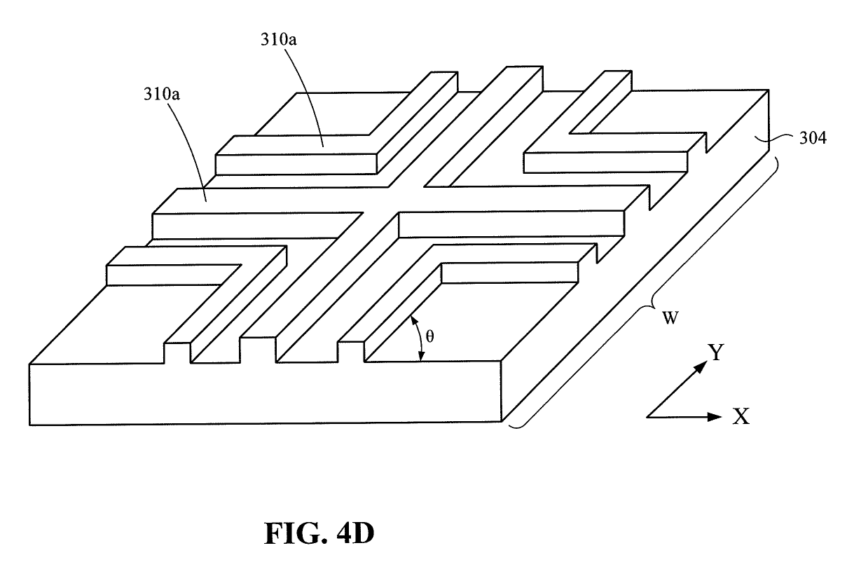

Cst=∈*(A/d) (E1),

wherein “∈” in equation (E1) is the dielectric constant of the insulating layer 306, “A” in equation (E1) is the opposite area between the first electrode 304 and the second electrode 308 and opposite area “A” is proportional to the average length “L′” in equation (E1). The average length “L′” is lateral curved length along the interdigitated space 316 filled with the insulating layer 306. In other words, the average length “L′” is equal to the lateral curved length from right side to left side of the first electrode 304 and the second electrode 308. Thus, the area “A” is equal to the multiplication of the average length “L′” and the width “W” (shown in FIG. 4A through FIG. 4D) of the first electrode 304 and the second electrode 308. If the average length “L′” is enlarged, the area “A” is also increased. Further, the thickness “d” is the distance of the insulating layer 306 between the first electrode 304 and the second electrode 308. In this case, the average length “L′” is positioned in half of the thickness “d” in equation (E1).

As shown in FIG. 3, when the dielectric constant “∈” and the thickness “d” of the insulating layer 306 are given, the capacitance value Cst of the storage capacitor architecture 300 is effectively enlarged if the opposite area “A” of the first electrode 304 and the second electrode 308. That is, the capacitance value Cst of the storage capacitor architecture 300 is effectively increased if the average length “L′” (greater than the conventional length “L”) between the first electrode 304 and the second electrode 308. Thus, the first concave and convex structure 310a of the first electrode 304 and the second concave and convex structure 310b of the second electrode 308 is capable of elongating the average length “L′” for increasing the area “A” between the first electrode 304 and the second electrode 308. Therefore, the present invention utilizes the first concave and convex structure 310a of the first electrode 304 and the second concave and convex structure 310b of the second electrode 308 for adding the opposite area “A” between the first electrode 304 and the second electrode 308 to increase the capacitance value Cst of the storage capacitor architecture 300 so that the aperture ratio of the pixel structure 200 keeps in constant. Alternatively, in comparison with conventional storage capacitor of the pixel, the present invention can adjust the average length “L′” to obtain the same capacitance value Cst in view of the value Cst in view of the same capacitance value Cst. In this case, the opposite area “A” between the first electrode 304 and the second electrode 308 is decreased to increase the aperture ratio of the pixel structure 200.

As shown in FIG. 2 and FIG. 3, the first electrode 304 includes a common line 205 according to one embodiment of the present invention. In another embodiment, the first electrode 304 includes a scan line 202.

Please refer to FIG. 3 and FIGS. 4A-4D. FIGS. 4A-4D are three-dimensional views of concave and convex structures 310a formed on the storage capacitor architecture 300 according to one embodiment of the present invention. The first concave and convex structure 310a of the first electrode 304 and the second concave and convex structure 310b of the second electrode 308 are selected from one consisting of a three-dimensional straight line shape (shown in FIG. 4A), a three-dimensional inclined line shape (shown in FIG. 4B), a three-dimensional concentric circle shape (shown in FIG. 4C) and a three-dimensional intersectional line shape (shown in FIG. 4D) wherein the first concave and convex structure 310a is opposite to the second concave and convex structure 310b to construct the interdigitated space 316. FIGS. 4A-4D show an example of the first concave and convex structure 310a of the first electrode 304. The second concave and convex structure 310b of the second electrode 308 is similar to the first concave and convex structure 310a of the first electrode 304.

In the three-dimensional straight line shape of FIG. 4A, the intervals between the first concave and convex structures of the first electrode 304 is equal or unequal. That is, the average length “L′” can be adjusted to change the size of the area “A” for increasing either the capacitance value Cst or the aperture ratio of the pixel structure 200. In the three-dimensional inclined line shape of FIG. 4B, the intervals between the first concave and convex structures of the first electrode 304 is equal or unequal. The included angle “θ” ranging from 0 to 90 degrees is defined as the first concave and convex structure 310a of the first electrode 304 and direction X. In the three-dimensional concentric circle shape of FIG. 4C, the intervals between the first concave and convex structures of the first electrode 304 along the direction X and direction Y is equal or unequal. The included angle “θ” ranging from 0 to 90 degrees is defined as the first concave and convex structure 310a of the first electrode 304 and direction X. In the three-dimensional intersectional line shape of FIG. 4D, the intervals between the first concave and convex structures of the first electrode 304 along the direction X and direction Y is equal or unequal. The included angle “θ” ranging from 0 to 90 degrees is defined as the first concave and convex structure 310a of the first electrode 304 and direction X.

Please continuously refer to FIG. 2 and FIG. 3. The pixel structure 200 with the storage capacitor architecture 300 include a thin-film transistor (TFT) 206, a first electrode 304, an insulating layer 306, a second electrode 308, a passivation layer 312 and a transparent electrode 314. The first electrode has a first concave and convex structure 310a. The insulating layer 306 is disposed on the first concave and convex structure 310a of the first electrode 304. The second electrode 308 is disposed on the insulating layer 306 and has a second concave and convex structure 310b wherein the first concave and convex structure 310a and the second concave and convex structure 310b form an interdigitated space 316 and the insulating layer 306 is disposed in the interdigitated space 316 to form the storage capacitor architecture 300. The passivation layer 312 is formed on the second electrode 308 and the insulating layer 306 wherein a portion of the second electrode 306 is exposed. The transparent electrode 314 is foamed on the passivation layer 312 for electrically connecting the exposed second electrode 308 with the TFT 206.

As shown in FIG. 2 and FIG. 3, the first electrode 304 includes a common line 205 according to one embodiment of the present invention. In another embodiment, the first electrode 304 includes a scan line 202.

Please refer to FIG. 3 and FIG. 4A-4D. FIGS. 4A-4D are three-dimensional views of concave and convex structures 310a formed on the storage capacitor architecture 300 according to one embodiment of the present invention. The first concave and convex structure 310a of the first electrode 304 and the second concave and convex structure 310b of the second electrode 308 are selected from one consisting of a three-dimensional straight line shape (shown in FIG. 4A), a three-dimensional inclined line shape (shown in FIG. 4B), a three-dimensional concentric circle shape (shown in FIG. 4C) and a three-dimensional intersectional line shape (shown in FIG. 4D).

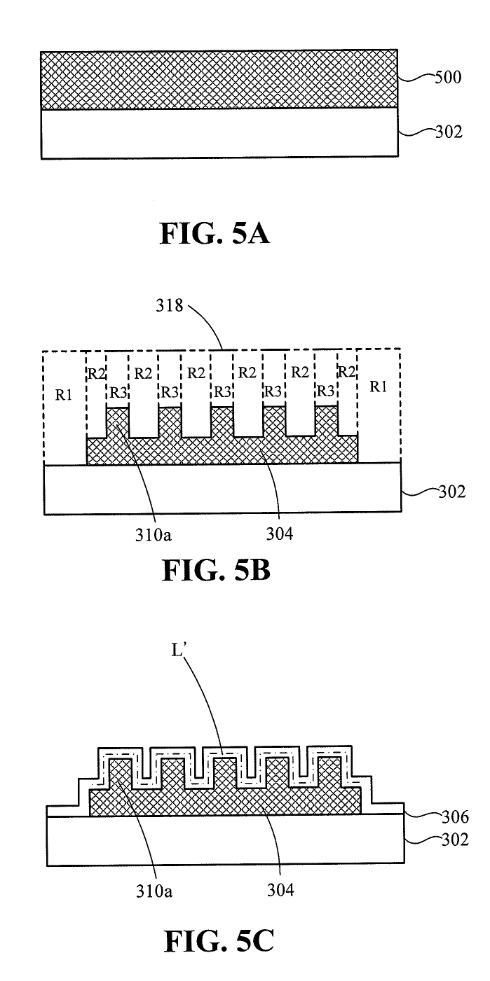

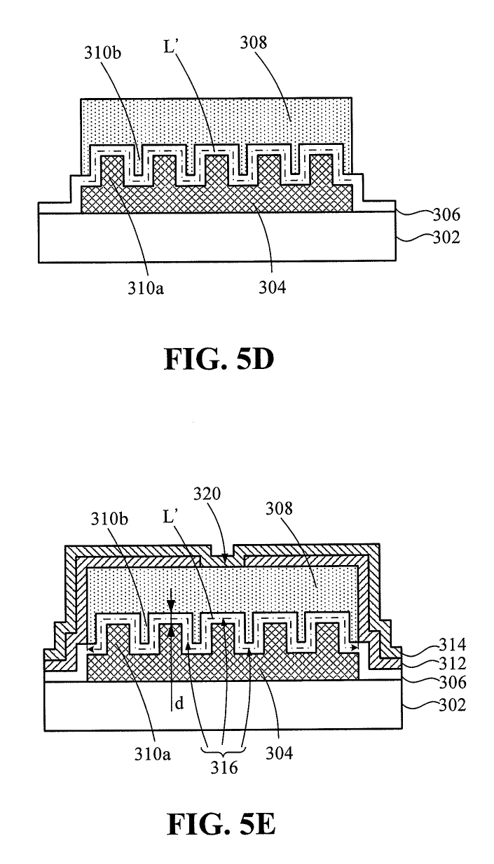

Please refer to FIGS. 5A-5E. FIGS. 5A-5E are flow chart of manufacturing method of the storage capacitor architecture 300 according to one embodiment of the present invention. The manufacturing method includes the following steps.

In FIG. 5A, a first conductive layer 500 is formed on a substrate 302. For example, a metal is deposited on the silicon substrate 302.

In FIG. 5B, the first conductive layer 500 is patterned for forming a first electrode 304 having a first concave and convex structure 310a. In one embodiment, a lithography process and an etching process is used to fours the first electrode 304 and the first concave and convex structure 310a. The first concave and convex structure 310a of the first electrode 304 is formed by either a gray tone mask or a half tone mask 318. The region R1 is complete exposed while performing the lithography process and the region R1 of the first conductive layer 500 is completely etched to reveal a portion of substrate 302. The region R2 is semi-exposed while performing the lithography process and the region R2 of the first conductive layer 500 is partially etched to leave a predetermined thickness of first conductive layer 500. The region R3 is unexposed while performing the lithography process and the region R3 of the first conductive layer 500 is not etched.

In FIG. 5C, an insulating layer 306 is formed on the substrate 302 and the first electrode 304. In one embodiment, silicon oxide or silicon nitride is formed on the substrate 302 and the first electrode 304.

In FIG. 5D, a second conductive layer (not shown) is formed on the insulating layer 306. In one case, a metal layer is deposited on the insulating layer 306.

Please refer to FIG. 5D continuously. The second conductive layer is patterned for forming a second electrode 308 having a second concave and convex structure 310b, wherein the first concave and convex structure 310a and the second concave and convex structure 310b form an interdigitated space 316 and the insulating layer 306 is disposed in the interdigitated space 316. In one embodiment, the material of the second electrode is either metal or indium tin oxide (ITO).

In FIG. 5E, a passivation layer 312 is formed on the second electrode 308 and the insulating layer 306 and a portion of the second electrode 308 is exposed. In one embodiment, silicon oxide or silicon nitride is formed on the second electrode 308 and the insulating layer 306. Further, the passivation layer 312 is etched to expose the second electrode 308 to generate a contact window 320 while performing a lithography process and an etching process.

Please refer to FIG. 5E continuously. A transparent electrode layer 314 is formed on the passivation layer 312 and the exposed second electrode 308 for electrically for electrically connecting the transparent electrode layer 314 to the exposed second electrode 308 via the contact window 320.

In one embodiment, the first electrode 304 includes either a common line 205 or a scan line 202, as shown in FIG. 2. Further, as shown in FIGS. 4A-4D, the first concave and convex structure 310a of the first electrode 304 and the second concave and convex structure 310b of the second electrode 308 are selected from one consisting of a three-dimensional straight line shape (shown in FIG. 4A), a three-dimensional inclined line shape (shown in FIG. 4B), a three-dimensional concentric circle shape (shown in FIG. 4C) and a three-dimensional intersectional line shape (shown in FIG. 4D).

To solve the problem of aperture ratio decrement, the present invention utilizes the first concave and convex structure of the first electrode and the second concave and convex structure of the second electrode to increase the average length for enlarging the opposite area of the first electrode and the second electrode to raise the capacitance of the storage capacitor architecture while the aperture ratio of the pixel structure is constant. Furthermore, in comparison with conventional storage capacitor of the pixel structure, the present invention can adjust the average length to obtain the same capacitance value. The opposite area between the first electrode and the second electrode is decreased to increase the aperture ratio of the pixel structure.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A storage capacitor architecture, comprising:
a first electrode having a first concave and convex structure;
an insulating layer disposed on the first concave and convex structure of the first electrode; and
a second electrode disposed on the insulating layer and having a second concave and convex structure, wherein the first concave and convex structure and the second concave and convex structure four an interdigitated space and the insulating layer is disposed in the interdigitated space.

2. The storage capacitor architecture of claim 1, wherein the first electrode comprises a common line.

3. The storage capacitor architecture of claim 1, wherein the first electrode comprises a scan line.

4. The storage capacitor architecture of claim 1, wherein the first concave and convex structure and the second concave and convex structure are selected from one consisting of a three-dimensional straight line shape, a three-dimensional inclined line shape, a three-dimensional concentric circle shape and a three-dimensional intersectional line shape.

5. A pixel structure having a storage capacitor architecture, the pixel structure comprising:
a thin-film transistor;
a first electrode having a first concave and convex structure;
an insulating layer disposed on the first concave and convex structure of the first electrode;
a second electrode disposed on the insulating layer and having a second concave and convex structure, wherein the first concave and convex structure and the second concave and convex structure form an interdigitated space and the insulating layer disposed in the interdigitated space;
a passivation layer farmed on the second electrode and the insulating layer wherein a portion of the second electrode is exposed; and
a transparent electrode formed on the passivation layer for electrically connecting the exposed second electrode with the thin-film transistor.

6. The pixel structure of claim 5, wherein the first electrode comprises a common line.

7. The pixel structure of claim 5, wherein the first electrode comprises a scan line.

8. The pixel structure of claim 5, wherein the first concave and convex structure and the second concave and convex structure are selected from one consisting of a three-dimensional straight line shape, a three-dimensional inclined line shape, a three-dimensional concentric circle shape and a three-dimensional intersectional line shape.

9. A method of manufacturing a storage capacitor architecture, the method comprising the steps of
(a) forming a first conductive layer on a substrate;
(b) patterning the first conductive layer for forming a first electrode having a first concave and convex structure;
(c) forming an insulating layer on the substrate and the first electrode;
(d) forming a second conductive layer on the insulating layer;
(e) pattering the second conductive layer for forming a second electrode having a second concave and convex structure, wherein the first concave and convex structure and the second concave and convex structure form an interdigitated space and the insulating layer is disposed in the interdigitated space;
(f) forming a passivation layer on the second electrode and the insulating layer and exposing a portion of the second electrode; and
(g) forming a transparent electrode layer on the passivation layer and the exposed second electrode for electrically connecting the transparent electrode layer to the exposed second electrode.

10. The method of claim 9, wherein the material of the first electrode is metal.

11. The method of claim 9, wherein the material of the second electrode is either metal or indium tin oxide.

12. The method of claim 9, wherein the first concave and convex structure of the first electrode is formed by either a gray tone mask or a half tone mask during the step (b).

13. The method of claim 9, wherein the first electrode comprises a common line.

14. The method of claim 9, wherein the first electrode comprises a scan line.

15. The method of claim 9, wherein the first concave and convex structure and the second concave and convex structure are selected from one consisting of a three-dimensional straight line shape, a three-dimensional inclined line shape, a three-dimensional concentric circle shape and a three-dimensional intersectional line shape.
